(19) United States
(12) Patent Application Publication
(10) Pub. No.: US 2019/0221702 A1
(43) Pub. Date: Jul. 18, 2019

(54) SOLAR CELL AND METHOD FOR PRODUCING SOLAR CELL

(71) Applicant: Panasonic Intellectual Property Management Co., Ltd., Osaka-shi (JP)

(72) Inventors: Kazunori Fujita, Osaka (JP); Keiichiro Masuko, Osaka (JP); Ayumu Yano, Osaka (JP)

(73) Assignee: Panasonic Intellectual Property Management Co., Ltd., Osaka (JP)

(21) Appl. No.: 16/360,589

(22) Filed: Mar. 21, 2019

Related U.S. Application Data
(63) Continuation of application No. PCT/JP2017/033017, filed on Sep. 13, 2017.

(30) Foreign Application Priority Data
Sep. 27, 2016 (JP) 2016-187721

(51) Int. Cl. H01L 31/0747; H01L 31/18; H01L 31/20; H01L 31/0216

(52) U.S. Cl. CPC H01L 31/0747; H01L 31/1868; H01L 31/1804; H01L 31/02167; H01L 31/202

(57) ABSTRACT

In an example embodiment, a method for producing a solar cell includes forming a passivation layer over a first principal surface of a crystalline silicon wafer; forming a substantially intrinsic i-type silicon layer over the passivation layer; forming n⁺ layers on and near principal surfaces of the wafer and turning the i-type silicon layer to be an n-type crystalline silicon layer by thermally diffusing an n-type dopant in the passivation layer, the i-type silicon layer, and the crystalline silicon wafer; and forming a p-type amorphous silicon layer on a second principal surface side of the crystalline silicon wafer in which the n⁺ layers are formed (n-type crystalline silicon wafer).

### CROSS REFERENCE TO RELATED APPLICATION

The present application is a continuation under 35 U.S.C. § 120 of PCT/JP2017/033017, filed Sep. 13, 2017, which is incorporated herein by reference, and which claimed priority to Japanese Patent Application No. 2016-187721 filed Sep. 27, 2016. The present application likewise claims priority under 35 U.S.C. § 119 to Japanese Patent Application No. 2016-187721 filed Sep. 27, 2016, the entire content of which is also incorporated herein by reference.

### TECHNICAL FIELD

The present disclosure relates to a solar cell and a method for producing a solar cell.

### BACKGROUND

There have been known solar cells including amorphous silicon layers formed over both sides of a crystalline silicon wafer. For example, Japanese Unexamined Patent Application Publication No. 2006-237452 discloses a solar cell including an n-type amorphous silicon layer formed over a light receiving surface of a crystalline silicon wafer and a p-type amorphous silicon layer formed over a back surface of the wafer. The solar cell disclosed in Japanese Unexamined Patent Application Publication No. 2006-237452 includes transparent conductive layers and collectors formed over the amorphous silicon layers.

### SUMMARY

In the art of solar cells, increasing the amount of light incident upon a silicon wafer, especially from the light receiving surface side, to improve the output characteristics of the cells is an important goal. While the amount of light incident from the light receiving surface side is increased by modifying, for example, the shape of the collectors in Japanese Unexamined Patent Application Publication No. 2006-237452 and other conventional techniques, further improvement is desired. Lowering the reverse breakdown voltage in solar cells is also desired.

According to one aspect of the present disclosure, there is provided a solar cell including an n-type crystalline silicon wafer, a light receiving surface side passivation layer, an n-type crystalline silicon layer, and a p-type amorphous silicon layer. The n-type crystalline silicon wafer incluhes n⁺ layers on and near principal surfaces of the wafer. The n layers contain a higher concentration of n-type dopant than elsewhere in the wafer. The light receiving surface side passivation layer is formed over a light receiving surface that is a first principal surface of the n-type crystalline silicon wafer. The light receiving surface side passivation layer is predominantly composed of a material selected from the group consisting of silicon oxide, silicon carbide, and silicon nitride. The n-type crystalline silicon layer is formed over the light receiving surface side passivation layer. The p-type amorphous silicon layer is formed on a back surface side over a second principal surface of the n-type crystalline silicon wafer. The light receiving surface side passivation layer contains the n-type dopant. The concentration of the n-type dopant in the light receiving surface side passivation layer and the n-type crystalline silicon layer is higher than or equal to the concentration of the n-type dopant in the n⁺ layer that is formed on the light receiving surface side of the n-type crystalline silicon wafer.

According to another aspect of the present disclosure, there is provided a method for producing a solar cell. The method includes forming a passivation layer over a first principal surface of a crystalline silicon wafer; forming a substantially intrinsic i-type silicon layer over the passivation layer; forming n⁺ layers on and near principal surfaces of the wafer and turning the i-type silicon layer to be an n-type crystalline silicon layer, and forming a p-type amorphous silicon layer on a second principal surface side of the crystalline silicon wafer in which the n⁺ layers are formed. The passivation layer is predominantly composed of a material selected from the group consisting of silicon oxide, silicon carbide, and silicon nitride. The n⁺ layers contain a higher concentration of n-type dopant than elsewhere in the wafer. Forming n⁺ layers and turning the i-type silicon layer into an n-type crystalline silicon layer are performed by thermally diffusing the n-type dopant in the passivation layer, the i-type silicon layer, and the crystalline silicon wafer.

An embodiment of the present disclosure provides a solar cell having good output characteristics and a low reverse breakdown voltage.

### BRIEF DESCRIPTION OF DRAWINGS

The figures depict one or more implementations in accordance with the present teachings, by way of example only, not by way of limitations. In the figures, like reference numerals refer to the same or similar elements.

FIG. 1 is a cross-sectional view of a solar cell according to an example embodiment.

FIG. 2 illustrate a method for producing a solar cell according to the example embodiment.

FIG. 3 is a cross-sectional view of a solar cell according to another example embodiment.

### DESCRIPTION OF EMBODIMENTS

The solar cell according to an embodiment of the present disclosure includes an n-type crystalline silicon layer formed on the light receiving surface side of a crystalline silicon wafer. As such, a greater amount of light is incident upon the wafer, and higher output characteristics are obtained, compared to conventional cells that include an amorphous silicon layer on the light receiving surface side. Further, a p-type amorphous silicon layer, which is deposited through a low-temperature process, is formed on the back surface side of the crystalline silicon wafer. As such, output characteristics can be improved at a lower production cost.

Further, the solar cell according to an embodiment of the present disclosure has n⁺ layers on and near the principal surfaces of the n-type crystalline silicon wafer, and does not include a silicon oxide layer but includes a p-type amorphous silicon layer over the back surface of the wafer. By employing such a structure, a solar cell having a high open-circuit voltage (Voc) and a low reverse breakdown voltage compared to conventional solar cells is obtained.

Example embodiments will be described in detail below with reference to the accompanying drawings. It should be noted that the solar cell and the method for producing a solar cell according to the present disclosure are not limited to the embodiments described below. As the drawings referred to in the description of the embodiments are schematic diagrams, the sizes or other features of components illustrated in the drawings should be interpreted in consideration of the following description.

The term “substantially” used in the present specification indicates that, for example, “substantially throughout” encompasses “throughout” itself and something like “practically throughout” as well. The term “n-type dopant” represents an impurity that serves as a donor, and the term “p-type dopant” represents an impurity that serves as an acceptor.

In the following description of the embodiments, an n-type crystalline silicon wafer, which is negatively doped (n-doped), is given as an example of the crystalline silicon wafer. However, a p-type crystalline silicon wafer, which is positively doped (p-doped), can also be used as the crystalline silicon wafer. In this case as well, a structure similar to the structure that includes an n-type crystalline silicon wafer can be used for a passivation layer, an n-type crystalline silicon layer, a p-type amorphous silicon layer, and other layers.

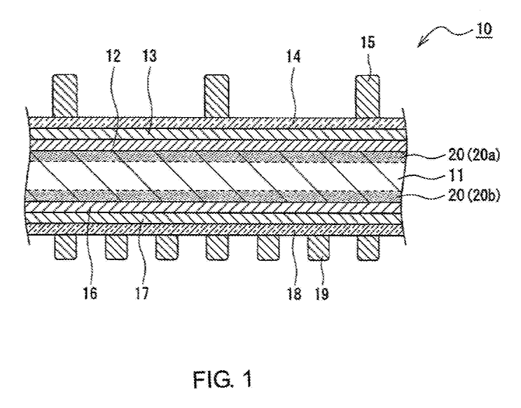

FIG. 1 is a cross-sectional view illustrating a solar cell 10 according to an example embodiment. As illustrated in FIG. 1, the solar cell 10 includes an n-type crystalline silicon wafer 11 that includes n⁺ layers 20 on and near the principal surfaces of the wafer where the concentration of an n-type dopant is higher than elsewhere in the wafer. More specifically, the n-type crystalline silicon wafer 11 includes the n⁺ layers 20 that are highly doped regions where the concentration of the n-type dopant is high, and includes a lightly doped region where the concentration of the n-type dopant is lower than that in the n⁺ layers 20, the lightly doped region being located away from the vicinities of the principal surfaces of the wafer. The solar cell 10 also includes a light receiving surface side passivation layer 12 (hereinafter simply referred to as “passivation layer 12”), an n-type crystalline silicon layer 13, and a p-type amorphous silicon layer 17.

The passivation layer 12, which will be described in detail below, is formed over a light receiving surface that is a first principal surface of the n-type crystalline silicon wafer 11, and is predominantly composed of silicon oxide, silicon carbide, or silicon nitride. The n-type crystalline silicon layer 13 is formed over the passivation layer 12. The p-type amorphous silicon layer 17 is formed on the back surface side over a second principal surface of the n-type crystalline silicon wafer 11. The passivation layer 12 contains the n-type dopant, and the concentration of the n-type dopant in the passivation layer 12 and the n-type crystalline silicon layer 13 is higher than or equal to the concentration of the n-type dopant in the n⁺ layer 20 that is formed on the light receiving surface side of the n-type crystalline silicon wafer 11.

The “light receiving surface” of the n-type crystalline silicon wafer 11 herein represents the principal surface upon which light is mainly incident (over 50% to 100%), and the “back surface” of the n-type crystalline silicon wafer 11 herein represents the principal surface that is opposite the light receiving surface. Surfaces that are perpendicular to the principal surfaces and extend in the thickness direction of the n-type crystalline silicon wafer 11 are referred to as “end surfaces”.

In a preferred embodiment, the solar cell 10 further includes a back surface side passivation layer 16 (hereinafter simply refened to as “passivation layer 16”) formed between the n-type crystalline silicon wafer 11 and the p-type amorphous silicon layer 17. The passivation layer 16 is predominantly composed of, for example, either substantially intrinsic amorphous silicon (hereinafter sometimes referred to as “i-type amorphous silicon”) or amorphous silicon having a lower concentration of a p-type dopant than that in the p-type amorphous silicon layer 17.

The crystallization ratio of the p-type amorphous silicon layer 17 is lower than the crystallization ratio of the n-type crystalline silicon layer 13, and the crystallization ratio of the n-type crystalline silicon layer 13 is lower than the crystallization ratio of the n-type crystalline silicon wafer 11. The crystallization ratios of the wafer and the layers are measured as an area ratio of regions where Si crystal lattice unit cells are observed, relative to a region that is observed using a transmission electron microscope (TEM) in the cross section of the wafer and the layers illustrated in FIG. 1. In other words, the longer the length of a region of a Si crystal lattice unit cell as viewed in the longitudinal direction, the higher the crystallization ratios of the wafer and the layers. As will be described in detail below, the n-type crystalline silicon wafer 11 is composed of monocrystalline silicon, and the n-type crystalline silicon layer 13 is composed of polycrystalline silicon. In a preferred embodiment, the length of a region of a Si crystal lattice unit cell formed in the p-type amorphous silicon layer 17 is less than 2 nm as viewed in the longitudinal direction.

The solar cell 10 includes a transparent conductive layer 14 formed over the n-type crystalline silicon layer 13 and a collector 15 formed over the transparent conductive layer 14. The solar cell 10 also includes a transparent conductive layer 18 formed over the p-type amorphous silicon layer 17 and a collector 19 formed over the transparent conductive layer 18. The transparent conductive layer 14 and the collector 15 constitute a light receiving surface electrode that collects electrons generated by the n-type crystalline silicon wafer 11. The transparent conductive layer 18 and the collector 19 constitute a back surface electrode that collects holes generated by the n-type crystalline silicon wafer 11. The solar cell 10 includes a pair of electrodes formed on the light receiving surface side and the back surface side of the n-type crystalline silicon wafer 11.

The n-type crystalline silicon wafer 11 may be an n-type polycrystalline silicon wafer, but in a preferred embodiment is an n-type monocrystalline silicon wafer. The concentration of the n-type dopant in regions of the n-type crystalline silicon wafer 11 other than the n⁺ layers 20, that is, in the remaining regions other than on and near the principal surfaces of the wafer, is, for example, 1×10¹⁴ atoms/cm³ to 1×10¹⁷ atoms/cm³. The n-type dopant is not particularly limited, but is typically phosphorus (P). The concentration of, for example, P or O contained in, for example, the n-type crystalline silicon wafer 11 is measured through secondary ion mass spectrometry (SIMS) or TEM-energy dispersive x-ray (TEM-EDX) spectroscopy.

The n-type crystalline silicon wafer 11 has a substantially square surface shape that is 120 man to 160 mm per side, and the thickness of the n-type crystalline silicon wafer 11 is, for example, 50 μm to 300 μm. A substantially square shape encompasses, for example, an octagon having alternate long and short sides that include two pairs of long sides in which the long sides in each pair are parallel to each other. The n-type crystalline silicon wafer 11 is typically produced by the Czochralski method (Cz method), but can also be produced by the epitaxial growth method.

The n-type crystalline silicon wafer 11 contains substantially no p-type dopant. However, the n-type crystalline silicon wafer 11 may contain a p-type dopant on and near its end surfaces. The concentration of the p-type dopant in the n-type crystalline silicon wafer 11 is 1×10¹⁴ atoms/cm³ or lower, which is lower than the 1×10¹⁵ atoms/cm³ detection limit of the SIMS. Because the p-type amorphous silicon layer 17 is deposited through a low-temperature process, substantially no diffusion of boron from the p-type amorphous silicon layer 17 to the n-type crystalline silicon wafer 11 occurs. Therefore, the solar cell 10 includes no composite defect resulting from diffusion of boron, and no reduction in lifetime of carriers caused by a composite defect occurs.

In a preferred embodiment, a texture structure (not illustrated) is formed on the surface of the n-type crystalline silicon wafer 11. The texture structure is an uneven surface structure for increasing the amount of light absorbed by the n-type crystalline silicon wafer 11 by suppressing surface reflection, and is formed on one of the light receiving surface and the back surface or on both of the light receiving surface and the back surface. The height of the projections and depressions in the texture structure is, for example, 1 μm to 15 μm.

One of the n⁺ layers 20 is formed on and near the light receiving surface of the n-type crystalline silicon wafer 11, and the other is formed on and near the back surface of the n-type crystalline silicon wafer 11. In the following description, the n⁺ layer 20 formed on the light receiving surface side of the n-type crystalline silicon wafer 11 is referred to as “n⁺ layer 20a”, and the n⁺ layer 20 formed on the back surface side of the n-type crystalline silicon wafer 11 is referred to as “n⁺ layer 20b”. By forming the n⁺ layers 20, the output characteristics of the solar cell 10 are improved, and the reverse breakdown voltage is lowered.

The concentration of the n-type dopant in the n⁺ layers 20 is preferably 1×10¹⁸ atoms/cm³ to 1×10²⁰ atoms/cm³ and is more preferably 1×10¹⁸ atoms/cm³ to 6×10¹⁸ atoms/cm³. The concentration of the n-type dopant in the n⁺ layer 20a formed on the light receiving surface side of the n-type crystalline silicon wafer 11 is, for example, lower than or equal to the concentration of the n-type dopant in the n⁺ layer 20b formed on the back surface side of the wafer. In other words, the concentration of the n-type dopant in the n⁺ layer 20a is either substantially the same as the concentration of the n-type dopant in the n⁺ layer 20b or lower than the concentration of the n-type dopant in the n⁺ layer 20b. In a preferred example, the concentration of the n-type dopant in the n⁺ layer 20a is 3×10¹⁷ atoms/cm³ to 6×10¹⁸ atoms/cm³. In a preferred example, the concentration of the n-type dopant in the n⁺ layer 20b is 1×10¹⁸ atoms/cm³ to 1×10²⁰ atoms/cm³.

The n⁺ layers 20 are formed to have a thickness of, for example, 1 μm or less as measured from the light receiving surface or the back surface of the n-type crystalline silicon wafer 11. The n⁺ layers 20 typically have a concentration gradient such that the deeper the depth, that is, the greater the distance from the light receiving surface or the back surface of the n-type crystalline silicon wafer 11, the lower the concentration of the n-type dopant. It should be noted that the n⁺ layers 20 may be formed over the entire surface of the n-type crystalline silicon wafer 11 and in the vicinity of the n-type crystalline silicon wafer 11, including the end surfaces of the n-type crystalline silicon wafer 11 and the vicinity thereof.

The passivation layer 12 is interposed between the light receiving surface of the n-type crystalline silicon wafer 11 and the n-type crystalline silicon layer 13, and suppresses the recombination of carriers on the light receiving surface side of the cell. The passivation layer 12 is formed substantially throughout the light receiving surface of the n-type crystalline silicon wafer 11. When the n-type crystalline silicon wafer 11 has a substantially square shape that is 120 mm to 160 mm per side, the passivation layer 12 formed substantially throughout may cover the entire surface of the substantially square shape, or may cover the entire surface except an outer surrounding region having a width of 2 mm or less as measured from ends of the substantially square shape. In a preferred embodiment, the passivation layer 12 is a thermally stable layer which, even upon exposure to elevated temperatures, will not exhibit impaired passivation characteristics.

The passivation layer 12 is, as described above, predominantly composed of silicon oxide (SiOₓ, where x≤2), silicon carbide (SiC), or silicon nitride (SiN). The passivation layer 12 may be predominantly composed of silicon oxide, silicon carbide, or silicon nitride that is blended with amorphous silicon. As described above, the passivation layer 12 contains an n-type dopant, and the concentration of the n-type dopant in the passivation layer 12 is higher than or equal to the concentration of the n-type dopant in the n⁺ layer 20a of the n-type crystalline silicon wafer 11. The thickness of the passivation layer 12 is, for example, 0.1 nm to 5.0 nm. The thickness of the passivation layer 12 (and other layers) is measured through observation of a cross section of the cell using a TEM.

When the passivation layer 12 is predominantly composed of silicon oxide, the concentration of oxygen in this layer is preferably 1.0×10²¹ atoms/cm³ or higher. For example, the concentration of oxygen in the passivation layer 12 is higher than the concentration of oxygen in the passivation layer 16. The concentration of the n-type dopant such as phosphorus in the passivation layer 12 is higher than the concentration of the p-type dopant such as boron in the passivation layer 16.

The concentration of the n-type dopant in the passivation layer 12 is preferably 1×10¹⁹ atoms/cm³ to 1×10²¹ atoms/cm³ and is more preferably 3×10¹⁹ atoms/cm³ to 5×10²⁰ atoms/cm³. The passivation layer 12 has a concentration gradient of the n-type dopant such that, for example, the closer to the n-type crystalline silicon wafer 11, the lower the concentration.

The n-type crystalline silicon layer 13 is formed over the light receiving surface of the n-type crystalline silicon wafer 11, with the passivation layer 12 between the two. Over the light receiving surface of the n-type crystalline silicon wafer 11, the n-type crystalline silicon layer 13 is formed substantially throughout the light receiving surface, with the passivation layer 12 between the two. As described above, the concentration of the n-type dopant in the n-type crystalline silicon layer 13 is higher than or equal to the concentration of the n-type dopant in the n⁺ layer 20a of the n-type crystalline silicon wafer 11. The thickness of the n-type crystalline silicon layer 13 is, for example, 5 nm to 20 nm and is preferably 8 nm to 15 nm.

The n-type crystalline silicon layer 13 is composed of n-doped polycrystalline silicon or microcrystalline silicon. The length of a region of a Si crystal lattice unit cell formed in the n-type crystalline silicon layer 13 is 2 nm or greater as viewed in the longitudinal direction. If regions where Si crystal lattice unit cells are observed are within this range, a high transmittance of sunlight is obtained. The absorption coefficient of the n-type crystalline silicon layer 13 in the wavelength range of 400 nm to 600 nm is lower than the absorption coefficient of the p-type amorphous silicon layer 17 in the same wavelength range and is, for example, 5×10⁴ to 4×10 cm⁻¹ at the wavelength of 420 nm. The absorption coefficients of the layers are determined through ellipsometry.

The concentration of the n-type dopant in the n-type crystalline silicon layer 13 is preferably 1×10¹⁹ atoms/cm³ to 1×10²² atoms/cm³ and is more preferably 3×10¹⁹ atoms/cm³ to 5×10²¹ atoms/cm³. The n-type crystalline silicon layer 13 has a concentration gradient of the n-type dopant such that, for example, the closer to the passivation layer 12, the lower the concentration. The resistivity of the n-type crystalline silicon layer 13 is higher than that of the transparent conductive layer 14 and is, for example, 0.1 mΩ·cm to 150 mΩ·cm.

The concentration of hydrogen in the n-type crystalline silicon layer 13 is lower than that in the p-type amorphous silicon layer 17. The concentration of hydrogen in the n-type crystalline silicon layer 13 is lower than that in the passivation layer 16. The concentration of hydrogen in the n-type crystalline silicon layer 13 is, for example, 1×10¹⁸ atoms/cm to 1×10²¹ atoms/cm³ and is preferably 7×10¹⁸ atoms/cm³ to 5×10⁰ atoms/cm³.

The index of refraction of the n-type crystalline silicon layer 13 in the wavelength range of 355 nm to 405 nm is preferably 2.5 times the index of refraction of the transparent conductive layer 14 or greater and is, for example, 2.5 times to 3.2 times. The indexes of refraction of the layers are determined using, for example, a spectroscopic ellipsometer. If the index of refraction of the n-type crystalline silicon layer 13 is within the above-described range, irregularity in color of the cell is reduced and good appearance is obtained.

The passivation layer 16 is interposed between the back surface of the n-type crystalline silicon wafer 11 and the p-type amorphous silicon layer 17, and suppresses the recombination of carriers on the back surface side of the cell. The passivation layer 16 is formed substantially throughout the back surface of the n-type crystalline silicon wafer 11. When the n-type crystalline silicon wafer 11 has a substantially square shape that is 120 mm to 160 mm per side, the passivation layer 16 formed substantially throughout may cover the entire surface of the substantially square shape or may cover the entire surface except an outer surrounding region having a width of 2 mm or less, as measured from ends of the substantially square shape.

In a preferred embodiment, the passivation layer 16 can be deposited at a temperature of about 200° C. The passivation layer 16 is less thermally stable than the passivation layer 12. In a preferred embodiment, the passivation layer 16 contains either i-type amorphous silicon or amorphous silicon having a lower dopant concentration than that of the p-type amorphous silicon layer 17. The thickness of the passivation layer 16 is greater than that of the passivation layer 12 and is, for example, 5 nm to 10 nm.

In a preferred embodiment, the passivation layer 16 is predominantly composed of i-type amorphous silicon, and may be an i-type amorphous silicon layer that is composed substantially of only i-type amorphous silicon. As described above, the concentration of oxygen in the passivation layer 16 is lower than that in the passivation layer 12, and the concentration of the p-type dopant such as boron in the passivation layer 16 is lower than the concentration of the n-type dopant such as phosphorus in the passivation layer 12.

The p-type amorphous silicon layer 17 is formed over the back surface of the n-type crystalline silicon wafer 11, with the passivation layer 16 between the two. Over the back surface of the n-type crystalline silicon wafer 11, the p-type amorphous silicon layer 17 is formed substantially throughout, with the passivation layer 16 between the two. Similarly to the passivation layer 16, the p-type amorphous silicon layer 17 formed substantially throughout may cover the entire surface of the substantially square shape or may cover the entire surface except an outer surrounding region having a width of 2 mm or less as measured from ends of the substantially square shape. The thickness of the p-type amorphous silicon layer 17 is, for example, 1 nm to 25 nm and is preferably 1 nm to 10 nm.

The concentration of the p-type dopant in the p-type amorphous silicon layer 17 is, for example, 1×10²⁰ atoms/cm³ or higher. The p-type dopant is not particularly limited, but is typically boron (B). The p-type amorphous silicon layer 17 contains, for example, boron substantially uniformly. It should be noted that the concentration of hydrogen in the p-type amorphous silicon layer 17 is higher than that in the n-type crystalline silicon layer 13.

The transparent conductive layer 14 is formed substantially throughout the surface on the light receiving surface side of the n-type crystalline silicon layer 13. The transparent conductive layer 18 is formed substantially throughout the surface on the back surface side of the p-type amorphous silicon layer 17. When the n-type crystalline silicon wafer 11 has a substantially square shape that is 120 mm to 160 mm per side, the transparent conductive layers 14 and 18 formed substantially throughout may cover the entire surface of the substantially square shape, or may cover the entire surface except an outer surrounding region having a width of 2 mm or less as measured from ends of the substantially square shape. Over the n-type crystalline silicon layer 13 and the p-type amorphous silicon layer 17 that are formed to cover the entire surface of the substantially square shape, the transparent conductive layers 14 and 18 may be respectively formed to cover the entire surface except an outer surrounding region having a width of 2 mm or less as measured from ends of the substantially square shape. The transparent conductive layers 14 and 18 are composed of a transparent electrically conductive oxide (for example, IWO or ITO) that is a metal oxide such as indium oxide (In₂O₃) or zinc oxide (ZnO) doped with, for example, tungsten (W), tin (Sn), or antimony (Sb). The thicknesses of the transparent conductive layers 14 and 18 are preferably 30 nm to 500 nm, and are particularly preferably 50 nm to 200 nm.

In a preferred embodiment, each of the collectors 15 and 19 includes a plurality of finger portions and a plurality of bus bar portions. The finger portions are narrow linear electrodes that are formed over a large area on the transparent conductive layers 14 and 18. The bus bar portions are narrow linear electrodes for collecting carriers from the finger portions and are formed to intersect the finger portions substantially at right angles. The collectors 15 and 19 are formed by respectively coating the transparent conductive layers 14 and 18 with an electrically conductive paste in a pattern that includes, for example, many finger portions and two or three bus bar portions. The electrically conductive paste for forming the collectors 15 and 19 may be formed by dispersing electrically conductive particles having a diameter of 1 nm to 50 μm composed of, for example, silver, copper, or nickel in a binder resin such as an acrylic resin, an epoxy resin, or phenol novolac.

In a preferred embodiment, the collector 19 is formed over a larger area than the collector 15, and the number of the finger portions of the collector 19 is greater than the number of the finger portions of the collector 15. Therefore, the area of the transparent conductive layer 18 covered by the collector 19 is greater than the area of the transparent conductive layer 14 covered by the collector 15. The collector 15 is thicker than the collector 19. However, the electrode structure is not particularly limited. For example, a metal layer serving as the collector of the back surface electrode may be formed substantially throughout over the transparent conductive layer 18.

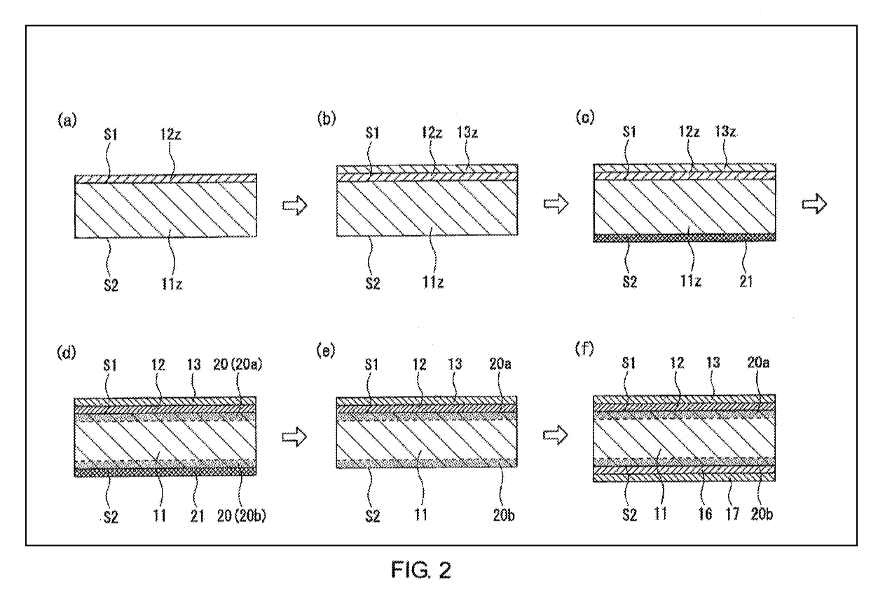

FIG. 2 illustrate an example method for producing the solar cell 10. A crystalline silicon wafer 11z is a silicon wafer that is being processed and that does not include the n⁺ layers 20. A passivation layer 12z and an i-type silicon layer 13z respectively constitute the passivation layer 12 and the n-type crystalline silicon layer 13 in a later step.

As illustrated in FIG. 2, the production process of the solar cell 10 includes the following steps:

(1) Forming the passivation layer 12z that is predominantly composed of silicon oxide, silicon carbide, or silicon nitride over a first principal surface S1 of the crystalline silicon wafer 11z;

(2) Forming the i-type silicon layer 13z that is substantially intrinsic over the passivation layer 12z;

(3) Forming the n⁺ layers 20 on and near the principal surfaces of the wafer where the concentration of an n-type dopant is higher than elsewhere in the wafer, and turning the i-type silicon layer 13z into the n-type crystalline silicon layer 13 by thermally diffusing the n-type dopant in the passivation layer 12z, the i-type silicon layer 13z, and the crystalline silicon wafer 11z; and

(4) Forming the p-type amorphous silicon layer 17 on a second principal surface S2 of the crystalline silicon wafer 11z in which the n⁺ layers 20 are formed (the n-type crystalline silicon wafer 11).

In the illustrated embodiment, the production process further includes the step of forming the passivation layer 16 (second passivation layer) between the n-type crystalline silicon wafer 11, that is, the crystalline silicon wafer 11z in which the n⁺ layers 20 are formed, and the p-type amorphous silicon layer 17. This step is performed between the above-described steps (3) and (4). The passivation layer 16 is, as described above, predominantly composed of either substantially intrinsic amorphous silicon or amorphous silicon having a lower concentration of a p-type dopant than that in the p-type amorphous silicon layer 17.

In the production process of the solar cell 10, first, the crystalline silicon wafer 11z that includes a texture structure is prepared. In a preferred embodiment, an n-type monocrystalline silicon wafer is used as the crystalline silicon wafer 11z. The texture structure can be formed by anisotropically etching the (100) plane of the monocrystalline silicon wafer using an alkaline solution. In this case, a structure including pyramidal projections and depressions having inclined surfaces on the (111) plane is formed on the surface of the monocrystalline silicon wafer. In a preferred embodiment, the texture structure is formed on the principal surfaces S1 and S2 of the crystalline silicon wafer 11z.

FIG. 2 illustrate the process from the deposition of the passivation layer 12z to the deposition of the p-type amorphous silicon layer 17. As illustrated in FIG. 2(a), first, the passivation layer 12z is formed on the first principal surface S1 of the crystalline silicon wafer 11z. The passivation layer 12z is, for example, formed substantially throughout the principal surface S1. The principal surface S1 on which the passivation layer 12z is formed serves as the light receiving surface of the solar cell 10, and the principal surface S2 is the back surface of the solar cell 10. The passivation layer 12z is predominantly composed of silicon oxide, silicon carbide, or silicon nitride, and contains no n-type dopant.

In a preferred embodiment, the passivation layer 12z is a silicon oxide film that is predominantly composed of silicon oxide. The deposition method for the silicon oxide film may be, for example, CVD or sputtering. When CVD is used, a silicon oxide film can be selectively formed on the principal surface S1 of the crystalline silicon wafer 11z. The concentration of oxygen in the silicon oxide film can be adjusted by varying the deposition conditions.

In this process, the surface of the crystalline silicon wafer 11z may be thermally oxidized in a high-temperature steam atmosphere of about 500° C. (steam oxidation method). Alternatively, the crystalline silicon wafer 11z may be immersed in heated nitric acid so that the surface of the wafer is wet-chemically oxidized (nitric acid oxidation method). However, when a silicon oxide film is formed on the principal surface S2 of the crystalline silicon wafer 11z, the silicon oxide film is removed from the principal surface S2 before the deposition of the passivation layer 16. The silicon oxide film formed on the principal surface S2 can also be used either as a diffusion adjusting film 21, which will be described below, or as a portion of the diffusion adjusting film 21.

Subsequently, as illustrated in FIG. 2(b), the i-type silicon layer 13z is deposited over the passivation layer 12z. The n-type silicon layer 13z is, for example, formed substantially throughout over the passivation layer 12z. The i-type silicon layer 13z may be any of an amorphous silicon film, a microcrystalline silicon film, or a polycrystalline silicon film. The deposition method for the i-type silicon layer 13z may be, for example, CVD or sputtering.

Subsequently, as illustrated in FIG. 2(c) to (e), the diffusion adjusting film 21 for suppressing the diffusion of the n-type dopant is formed over the second principal surface S2 of the crystalline silicon wafer 11z, and after that, the n-type dopant is thermally diffused into the wafer. The diffusion adjusting film 21 is, for example, formed substantially throughout the principal surface S2 of the crystalline silicon wafer 11z. Then, the diffusion adjusting film 21 is removed before the p-type amorphous silicon layer 17 is formed. In the illustrated embodiment, the diffusion adjusting film 21 is removed before the passivation layer 16 is formed.

The diffusion adjusting film 21 performs the function of adjusting the concentration of the n-type dopant in the n⁺ layer 20b that is formed on the principal surface S2 side of the crystalline silicon wafer 11z. When the diffusion adjusting film 21 is formed, because the n-type dopant is diffused into the crystalline silicon wafer 11z via the diffusion adjusting film 21, the concentration of the n-type dopant in the n⁺ layer 20b is lower than that in the structure wherein the diffusion adjusting film 21 is not formed. It should be noted that on the principal surface S1 side of the crystalline silicon wafer 11z, the n-type dopant is diffused into the crystalline silicon wafer 11z via the passivation layer 12z and the i-type silicon layer 13z. Therefore, when the concentrations of the n-type dopant in the n⁺ layers 20a and 20b are adjusted to a similar level, in a preferred embodiment, the diffusion adjusting film 21 is formed.

The diffusion adjusting film 21 is predominantly composed of silicon oxide. However, the composition of the diffusion adjusting film 21 is not particularly limited, and any material that can be removed in a later step may be used. The diffusion adjusting film 21 may be, for example, predominantly composed of silicon nitride. The deposition method for the diffusion adjusting film 21 may be, for example, CVD or sputtering. The thickness of the diffusion adjusting film 21 is, for example, 1 nm to 20 nm, and the concentration of the n-type dopant in the n⁺ layer 20b can be easily adjusted by varying the thickness. When the concentrations of the n-type dopant in the n⁺ layers 20a and 20b are adjusted to a similar level, the thickness of the diffusion adjusting film 21 may be substantially the same as the total thickness of the passivation layer 12z and the i-type silicon layer 13z. It should be noted that the n-type dopant may be diffused without the diffusion adjusting film 21, and with the principal surface S2 side of the crystalline silicon wafer 11z being exposed, so that the concentration of the n-type dopant in the n⁺ layer 20b can be set to be higher than that in the n⁺ layer 20a.

In the step of diffusing the n-type dopant into the crystalline silicon wafer 11z, in a preferred embodiment, the n-type dopant is thermally diffused such that the concentration of the n-type dopant in the n⁺ layers 20 is 1×10¹⁸ atoms/cm³ to 1×10²⁰ atoms/cm³. The diffusion of the n-type dopant is performed by, for example, a thermal diffusion method using phosphoyl chloride (POCl₃) vapor. The thermal diffusion of phosphorus using phosphoryl chloride is performed at a temperature of, for example, 800° C. to 900° C.

In the illustrated embodiment, the n-type dopant is diffused into, for example, the crystalline silicon wafer 11z via the passivation layer 12z and the i-type silicon layer 13z on the principal surface S1 side of the crystalline silicon wafer 11z, and via the diffusion adjusting film 21 on the principal surface S2 side of the crystalline silicon wafer 11z. Then, the n⁺ layers 20a and 20b are formed in the crystalline silicon wafer 11z, and the passivation layer 12z and the i-type silicon layer 13z are n-doped. The n-type crystalline silicon wafer 11, the passivation layer 12, and the n-type crystalline silicon layer 13 are formed in this manner. The n-type crystalline silicon layer 13 is formed by, for example, after the formation of the i-type silicon layer 13z that is amorphous over the passivation layer 12z, heating the layers without supply of the n-type dopant to crystallize the silicon layer, and subsequently heating the layers while the n-type dopant is being supplied. However, the method for forming the n-type crystalline silicon layer 13 is not limited to this example. The crystallization of the i-type silicon layer 13z and the diffusion of the impurity may be performed in the same heating step by heating the layers while the n-type dopant is being supplied.

The diffusion adjusting film 21 is, as described above, removed after the step of thermally diffusing the n-type dopant. When the diffusion adjusting film 21 is a silicon oxide film, the diffusion adjusting film 21 can be removed by immersing the n-type crystalline silicon wafer 11 in hydrogen fluoride. It should be noted that because the n-type crystalline silicon layer 13 resists hydrogen fluoride, the passivation layer 12 that is covered by the n-type crystalline silicon layer 13 is not removed when the n-type crystalline silicon wafer 11 is immersed in hydrogen fluoride.

The step of thermally diffusing the n-type dopant may be followed by sintering the n-type crystalline silicon wafer 11 in the presence of hydrogen (H₂). The hydrogen sintering is performed in, for example, a forming gas containing hydrogen gas diluted with an inert gas such as nitrogen gas through heat treatment of the n-type crystalline silicon wafer 11 at a temperature of about 350° C. to about 450° C. This step allows replenishment of hydrogen, which has been removed from the n-type crystalline silicon wafer 11 during the thermal diffusion of the n-type dopant.

Subsequently, as illustrated in FIG. 2(f), the passivation layer 16 and the p-type amorphous silicon layer 17 are deposited, in that order, over the principal surface S2 of the n-type crystalline silicon wafer 11. In a preferred embodiment, the passivation layer 16 is an i-type amorphous silicon film. For example, the i-type amorphous silicon film is formed substantially throughout the principal surface S2, and the p-type amorphous silicon layer 17 is formed substantially throughout over the i-type amorphous silicon film.

The passivation layer 16 and the p-type amorphous silicon layer 17 are formed through CVD or sputtering by placing the n-type crystalline silicon wafer 11, that is clean, in a vacuum chamber. When the passivation layer 16 formed through CVD is an i-type amorphous silicon film, for example, a material gas containing silane gas diluted with hydrogen (H₂) is used for the deposition by CVD. When the p-type amorphous silicon layer 17 is deposited through CVD, for example, a material gas containing silane gas to which diborane (B₂H₆) is added and which is diluted with hydrogen is used. The dopant concentration of the p-type amorphous silicon layer 17 can be adjusted by varying the mixture concentration of diborane.

Next, the transparent conductive layers 14 and 18 are respectively formed over the n-type crystalline silicon layer 13 and over the p-type amorphous silicon layer 17, and the collectors 15 and 19 are respectively formed over the transparent conductive layers 14 and 18 (not illustrated). The transparent conductive layers 14 and 18 are formed through, for example, sputtering. The collectors 15 and 19 are, for example, formed by applying an electrically conductive paste containing silver (Ag) particles over the transparent conductive layers through, for example, screen printing. The solar cell 10 illustrated in FIG. 1 is obtained in this manner.

The solar cell 10 produced through the above-described method has advantages in that it can be produced at low cost, and in that it has a high open-circuit voltage and good output characteristics, and also has a low reverse breakdown voltage. Additionally, the uniformity in color is high, resulting in good appearance. Also, the durability is good.

It should be noted that although, in the illustrated embodiment, the passivation layer 12 and the n-type crystalline silicon layer 13 are individually deposited and formed, the method for producing a solar cell according to the present disclosure is not limited to such a method for formation. For example, an i-type amorphous silicon film containing oxygen is formed as an initial thin film that will later be the passivation layer 12 and the n-type crystalline silicon layer 13. Subsequently, heat treatment is performed at a temperature of about 950° C. while the n-type dopant is being supplied. As a result, the i-type amorphous silicon film containing oxygen that is present near the interface with the crystalline silicon wafer 11z may form a silicon oxide layer, and the i-type amorphous silicon film containing oxygen that is located away from the interface with the crystalline silicon wafer 11z may form an n-type crystalline silicon layer.

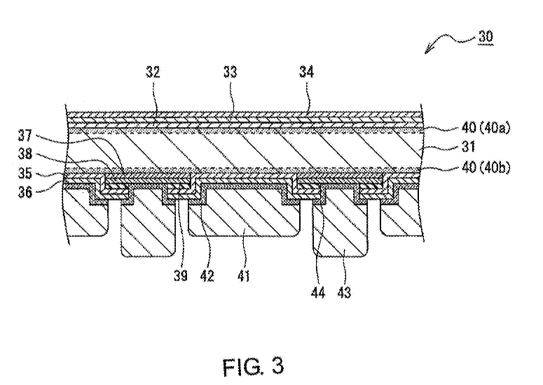

FIG. 3 is a cross-sectional view illustrating a solar cell 30 according to another example embodiment. As illustrated in FIG. 3, the solar cell 30 includes an electrode only on the back surface side of an n-type crystalline silicon wafer 31. As such, the solar cell 30 differs from the solar cell 10 that includes electrodes on both the light receiving surface side and the back surface side of the n-type crystalline silicon wafer. Similarly to the n-type crystalline silicon wafer 11, the n-type crystalline silicon wafer 31 includes n⁺ layers 40 on and near the principal surfaces of the wafer where the concentration of an n-type dopant is higher than elsewhere in the wafer. In a preferred embodiment, the concentration of the n-type dopant in the n⁺ layers 40 is 1×10¹⁸ atoms/cm³ to 1×10²⁰ atoms/cm³. The concentration of the n-type dopant in an n⁺ layer 40a is, for example, lower than or equal to the concentration of the n-type dopant in an n⁺ layer 40b.

The solar cell 30 includes a light receiving surface side passivation layer 32 (hereinafter simply referred to as “passivation layer 32”) formed over the light receiving surface of the n-type crystalline silicon wafer 31 and an n-type crystalline silicon layer 33 formed over the passivation layer 32. For the passivation layer 32 and the n-type crystalline silicon layer 33, strnctures similar to the passivation layer 12 and the n-type crystalline silicon layer 13 of the solar cell 10 can be respectively used. The passivation layer 32 contains the n-type dopant, and the concentration of the n-type dopant in the passivation layer 32 and the n-type crystalline silicon layer 33 is higher than or equal to the concentration of the n-type dopant in the n⁺ layer 40a of the n-type crystalline silicon wafer 31.

The solar cell 30 includes a protective layer 34 over the n-type crystalline silicon layer 33. The protective layer 34 protects, for example, the n-type crystalline silicon layer 33 and suppresses reflection of sunlight from the cell surface. In a preferred embodiment, the protective layer 34 is composed of an optically transparent material and is, for example, predominantly composed of an insulating material such as silicon oxide, silicon nitride, or silicon oxynitride.

The solar cell 30 includes back surface side passivation layers 35 and 37 (hereinafter simply referred to as “passivation layers 35 and 37”), a p-type amorphous silicon layer 36, and an n-type amorphous silicon layer 38. The passivation layer 35 is formed over the back surface of the n-type crystalline silicon wafer 31, and is interposed between the n-type crystalline silicon wafer 31 and the p-type amorphous silicon layer 36. The passivation layer 37 is formed over the back surface of the n-type crystalline silicon wafer 31, and is interposed between the n-type crystalline silicon wafer 31 and the n-type amorphous silicon layer 38. The p-type amorphous silicon layer 36 and the n-type amorphous silicon layer 38 respectively form a p-type region and an n-type region on the back surface side of the n-type crystalline silicon wafer 31.

In a preferred embodiment, the area of the p-type region formed over the back surface of the n-type crystalline silicon wafer 31 is larger than the area of the n-type region formed over the back surface of the n-type crystalline silicon wafer 31. The p-type region and the n-type region are, for example, disposed alternately in one direction and are formed in a pattern like the teeth of combs that mesh with each other as viewed in a top view. In the solar cell 30, a portion of the p-type region overlaps a portion of the n-type region, and the p-type region and the n-type region are formed with no clearance between them over the back surface of the n-type crystalline silicon wafer 31. In the portion where the p-type region and the n-type region overlap each other, an insulating layer 39 is disposed between these regions. The insulating layer 39 is predominantly composed of, for example, silicon oxide, silicon nitride, or silicon oxynitride. The insulating layer 39 may be composed of the same material as the protective layer 34.

The passivation layer 35 is predominantly composed of either i-type amorphous silicon or amorphous silicon having a lower concentration of a p-type dopant than that in the p-type amorphous silicon layer 36. The passivation layer 37 is predominantly composed of either i-type amorphous silicon or amorphous silicon having a lower concentration of an n-type dopant than that in the n-type amorphous silicon layer 38. For the p-type amorphous silicon layer 36, a structure similar to the p-type amorphous silicon layer 17 of the solar cell 10 can also be used. The n-type amorphous silicon layer 38 is an n-doped amorphous silicon layer. The concentration of the n-type dopant in the n-type amorphous silicon layer 38 is, for example, 1×10²⁰ atoms/cm³ or higher. The n-type amorphous silicon layer 38 typically contains the n-type dopant substantially uniformly. The amorphous silicon layers have a higher concentration of hydrogen and a lower density than those of the n-type crystalline silicon layer 33.

The solar cell 30 includes a transparent conductive layer 42 and a collector 41 that are formed over the p-type amorphous silicon layer 36 and a transparent conductive layer 44 and a collector 43 that are formed over the n-type amorphous silicon layer 38. The transparent conductive layer 42 and the collector 41 constitute a p-side electrode that is formed over the p-type region, and the transparent conductive layer 44 and the collector 43 constitute an n-side electrode that is formed over the n-type region. The transparent conductive layers 42 and 44 are isolated from each other at positions corresponding to the insulating layer 39. The collectors 41 and 43 are respectively formed over the transparent conductive layers 42 and 44. The collectors 41 and 43 may be formed using an electrically conductive paste and, in a preferred embodiment, are formed through electroplating. The collectors 41 and 43 are, for example, composed of a metal such as nickel (Ni), copper (Cu), or silver (Ag) and may have a layered structure of a Ni layer and a Cu layer. In order to improve the corrosion resistance, the collectors 41 and 43 may have a tin (Sn) layer on the outermost surface.

The solar cell 30 can be produced in a similar manner to the manner in which the solar cell 10 is produced. Specifically, the same process as performed for the solar cell 10 can be used for forming the n-type crystalline silicon wafer 31, the passivation layer 32, and the n-type crystalline silicon layer 33 (see FIG. 2(a) to (e)). The protective layer 34, the p-type region, the n-type region, the insulating layer 39, the transparent conductive layers 42 and 44, and the collectors 41 and 43 can be formed in a similar manner to the manner used for a conventional known solar cell that includes an electrode only on the back surface side. Similarly to the solar cell 10, the solar cell 30 has advantages in that it can be produced at low cost, and in that it has a high open-circuit voltage and good output characteristics, and also has a low reverse breakdown voltage.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A method for producing a solar cell, the method comprising:
forming a first passivation layer over a first principal surface of a crystalline silicon wafer, the first passivation layer being predominantly composed of a material selected from the group consisting of silicon oxide, silicon carbide, and silicon nitride;
forming a substantially intrinsic i-type silicon layer over the first passivation layer;
forming n⁺ layers on and near principal surfaces of the wafer, the n⁺ layers containing an n-type dopant in a concentration higher than elsewhere in the wafer, and turning the i-type silicon layer into an n-type crystalline silicon layer by thermally diffusing the n-type dopant in the first passivation layer, the i-type silicon layer, and the crystalline silicon wafer; and
forming a p-type amorphous silicon layer on a second principal surface side of the crystalline silicon wafer in which the n⁺ layers are formed.

2. The method according to claim 1, further comprising:
forming a diffusion adjusting film over the second principal surface of the crystalline silicon wafer for suppressing diffusion of the n-type dopant, and after that, thermally diffusing the n-type dopant into the wafer; and
removing the diffusion adjusting film before the p-type amorphous silicon layer is formed.

3. The method according to claim 2, wherein the diffusion adjusting film is predominantly composed of silicon oxide.

4. The method according to claim 1, wherein the n-type dopant is thermally diffused such that the concentration of the n-type dopant in the n⁺ layers is 1×10¹⁸ atoms/cm³ to 1×10²⁰ atoms/cm³.

5. The method according to claim 1, further comprising forming a second passivation layer between the crystalline silicon wafer in which the n⁺ layers are formed and the p-type amorphous silicon layer,
wherein the second passivation layer is predominantly composed of either substantially intrinsic amorphous silicon or amorphous silicon having a lower concentration of a p-type dopant than that in the p-type amorphous silicon layer.

6. The method according to claim 1, wherein the n-type crystalline silicon layer is formed by crystallizing the i-type silicon layer that has been formed over the first passivation layer, the i-type silicon layer being amorphous before the crystallization.

7. The method according to claim 1, wherein forming the n⁺ layers and turning the i-type silicon layer into the n-type crystalline silicon layer are performed by thermally diffusing the n-type dopant with the second principal surface of the crystalline silicon wafer being exposed.

8. A solar cell comprising:
an n-type crystalline silicon wafer including n⁺ layers on and near principal surfaces of the wafer, the n⁺ layers containing an n-type dopant in a concentration higher than elsewhere in the wafer;
a light receiving surface side passivation layer formed over a light receiving surface that is a first principal surface of the n-type crystalline silicon wafer, the light receiving surface side passivation layer being predominantly composed of a material selected from a group consisting of silicon oxide, silicon carbide, and silicon nitride:
an n-type crystalline silicon layer formed over the light receiving surface side passivation layer, and
a p-type amorphous silicon layer formed on a back surface side over a second principal surface of the n-type crystalline silicon wafer,
wherein the light receiving surface side passivation layer contains the n-type dopant, and
wherein the concentration of the n-type dopant in the light receiving surface side passivation layer and the n-type crystalline silicon layer is higher than or equal to the concentration of the n-type dopant in the n⁺ layer that is formed on the light receiving surface side of the n-type crystalline silicon wafer.

9. The solar cell according to claim 8, wherein the concentration of the n-type dopant in the n⁺ layers is 1×10¹⁸ atoms/cm³ to 1×10²⁰ atoms/cm³.

10. The solar cell according to claim 8, wherein the concentration of the n-type dopant in the n⁺ layer that is formed on the light receiving surface side of the n-type crystalline silicon wafer is lower than or equal to the concentration of the n-type dopant in the n⁺ layer that is formed on the back surface side of the wafer.

11. The solar cell according to claim 8, further comprising a back surface side passivation layer formed between the n-type crystalline silicon wafer and the p-type amorphous silicon layer,
wherein the back surface side passivation layer is predominantly composed of either substantially intrinsic amorphous silicon or amorphous silicon having a lower concentration of a p-type dopant than that in the p-type amorphous silicon layer.
